(19) United States
(12) Patent Application Publication
(10) Pub. No.: US 2012/0043639 A1
(43) Pub. Date: Feb. 23, 2012

(54) FABRICATING METHOD AND STRUCTURE OF SUBMOUNT

(75) Inventor: Taung-Yu LI, Chiayi City (TW)

(73) Assignee: MOS Art Pack Corporation, Hsinchu (TW)

(21) Appl. No.: 12/859,376

(22) Filed: Aug. 19, 2010

(51) Int. Cl. H01L 29/06; H01L 21/762

(52) U.S. Cl. 257/506; 438/424; 257/E21.546; 257/E29.02

(57) ABSTRACT

A fabricating method and structure of a submount are provided. The submount includes a semiconductor substrate, a first electrode, a second electrode and a first insulating adhesive member. The fabricating method of the submount includes the following steps. A semiconductor substrate is provided. An isolating groove is formed on a first surface of the semiconductor substrate, thereby defining a first region and a second region. A first electrode is formed on the first surface in the first region and a second electrode is formed on the first surface in the second region. A first insulating adhesive member is filled in the isolating groove. The semiconductor substrate is thinned from the second surface so as to expose the first insulating adhesive member from the second surface, thereby insulating the first region of the semiconductor substrate from the second region of the semiconductor substrate.

### BACKGROUND

1. Field of the Invention

The present invention relates to a fabricating method and structure of a submount, and particularly to a fabricating method and structure of a submount for light emitting diode (LED).

2. Description of the Related Art

The LED is a new generation lighting component. Nowadays, the LED has been widely used in various devices because of its advantages of low power, long life, and so on. However, when the LED emits light, amount of heat is generated from the LED. If the heat cannot be dissipated, a temperature of the LED will increase, thereby affecting the light emitting efficiency, stability and the life. Furthermore, the higher the temperature is, the greater the effect caused by the high temperature is.

Therefore, in a packaging process of the LED, a single LED chip or a number of LED chips is/are mounted on a submount. The submount can be configured for improving thermal dissipation. In general, a conventional submount is mostly made of a thermal dissipation material such as metal or ceramic. However, because the metal is a good electrical conductor, it is necessary to form a number of insulating structures. Thus, it is very complex to fabricate the metal submount. On the other hand, because the ceramic is prone to being broken, it is difficult to process the ceramic submount.

Therefore, what is needed is an easy fabricating method of a submount and a submount with low cost so as to overcome the above disadvantages.

### BRIEF SUMMARY

The present invention is directed to a fabricating method of a submount, which can be applied to an LED package to overcome the disadvantages of a conventional fabricating method such as high cost and poor thermal dissipation.

The present invention is also directed to a submount, which can be applied to a LED package to overcome the disadvantages of the conventional submount for LED such as high cost and poor thermal dissipation.

The present invention provides a fabricating method of a submount, which includes the following steps. A semiconductor substrate is provided. The semiconductor includes a first surface and a second surface opposite to the first surface. An isolating groove is formed on the first surface, thereby defining a first region and a second region of the semiconductor substrate. A first electrode is formed on the first surface in the first region and a second electrode is formed on the first surface in the second region. A first insulating adhesive member is filled in the isolating groove. The semiconductor substrate is thinned from the second surface of the semiconductor substrate so as to expose the first insulating adhesive member from the second surface, thereby insulating the first region from the second region of the semiconductor substrate.

The present invention also provides a submount. The submount includes a semiconductor substrate, a first electrode, a second electrode and a first insulating adhesive member. The semiconductor includes a first surface and a second surface opposite to the first surface. The first surface includes an isolating groove, thereby defining a first region and a second region of the semiconductor substrate. The first electrode is formed on the first surface in the first region, and the second electrode is formed on the first surface in the second region. The first electrode and the second electrode are configured for electrically connecting two electrodes of an electronic component. The first insulating adhesive member is filled in the isolating groove. In a process of thinning the semiconductor substrate from the second surface, the first insulating adhesive member is exposed, thereby insulating the first region of the semiconductor substrate from the second region of the semiconductor substrate.

In one embodiment of the present invention, the semiconductor substrate is selected from a group consisting of a silicon substrate, a germanium substrate and a gallium arsenide substrate. A depth of the isolating groove is more than a distance between a bottom of the isolating groove and the second surface.

In one embodiment of the present invention, forming the first electrode and the second electrode further includes the following steps. An electrical conductive layer is formed on the first surface of the semiconductor substrate. A photolithography process is performed on the electrical conductive layer to define a first electrical conductor and a second electrical conductor. The first electrical conductor and the second electrical conductor are respectively formed in the first region and the second region. An electroplating process is applied to the first electrical conductor and the second electrical conductor so as to form the first electrode and the second electrode.

In one embodiment of the present invention, filling the first insulating adhesive member in the isolating groove further includes the following steps. An insulating adhesive material is heated. The heated insulating adhesive material is filled in the isolating groove through an adhesive injecting machine. The insulating adhesive material is solidified so as to form the first insulating adhesive member.

In one embodiment of the present invention, thinning the semiconductor substrate further includes the following steps. The second surface of the semiconductor is ground. An etching process is applied to the second surface of the ground semiconductor substrate so that the first insulating adhesive member is exposed from the second surface.

In one embodiment of the present invention, the etching process is either a dry etching process or a wet etching process. In a process of forming the isolating groove, a number of cutting notches are further formed on the first surface of the semiconductor substrate. A number of interconnecting electrodes are formed in the cutting notches correspondingly. Each of the interconnecting electrodes is electrically connected to the corresponding first electrode or the corresponding second electrode.

In one embodiment of the present invention, the fabricating method further includes the following steps. A second insulating adhesive member is filled in each of the cutting notches. A third electrode and a fourth electrode are formed on the second surface of the thinned semiconductor substrate. The third electrode and the fourth electrode are respectively electrically connected to the interconnecting electrode in the corresponding cutting notch. Forming the third electrode and the fourth electrode further includes the following steps. An electrical conductive layer is formed on the second surface of the thinned semiconductor substrate. A photolithography process is performed on the electrical conductive layer to define a third electrical conductor and a fourth electrical conductor. An electroplating process is applied to the third electrical conductor and the fourth electrical conductor so as to form the third electrode and the fourth electrode.

In one embodiment of the present invention, the first electrode and the second electrode respectively include a titanium-copper alloy layer and a copper layer. The third electrode and the fourth electrode respectively include a titanium-copper alloy layer and a copper layer.

In one embodiment of the present invention, the first insulating adhesive member and the second insulating adhesive member are respectively selected from a group consisting of epoxy, polyurethane, silicone and acrylic.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

These and other features and advantages of the various embodiments disclosed herein will be better understood with respect to the following description and drawings, in which like numbers refer to like parts throughout, and in which:

FIGS. 1A-1H illustrate a process flow of a fabricating method of a submount in accordance with an embodiment of the present invention.

FIGS. 2A-2E illustrate schematic views of testing a submount and packaging an LED using the submount in accordance with an embodiment of the present invention.

FIG. 3A illustrates a top, schematic view of a submount having an LED mounted thereon in accordance with an embodiment of the present invention.

FIG. 3B illustrates a top, schematic view of a submount having a number of LEDs mounted thereon in accordance with an embodiment of the present invention.

FIGS. 3C and 3D illustrate top, schematic views of submounts having a third insulating adhesive member in accordance with an embodiment of the present invention.

FIG. 4A illustrates a cross-sectional, schematic view of a submount having an LED in flip chip package in accordance with an embodiment of the present invention.

FIG. 4B illustrates a top, schematic view of a submount having an LED in flip chip package in accordance with an embodiment of the present invention.

### DETAILED DESCRIPTION

It is to be understood that other embodiment may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted,” and variations thereof herein are used broadly and encompass direct and indirect connections, couplings, and mountings.

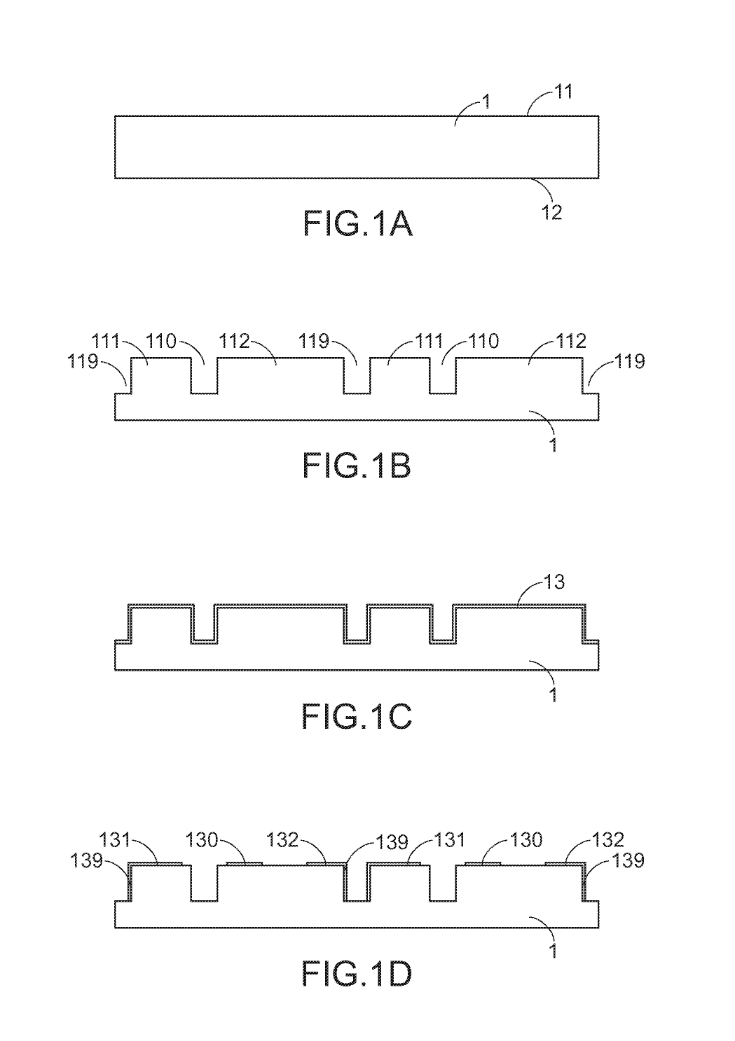

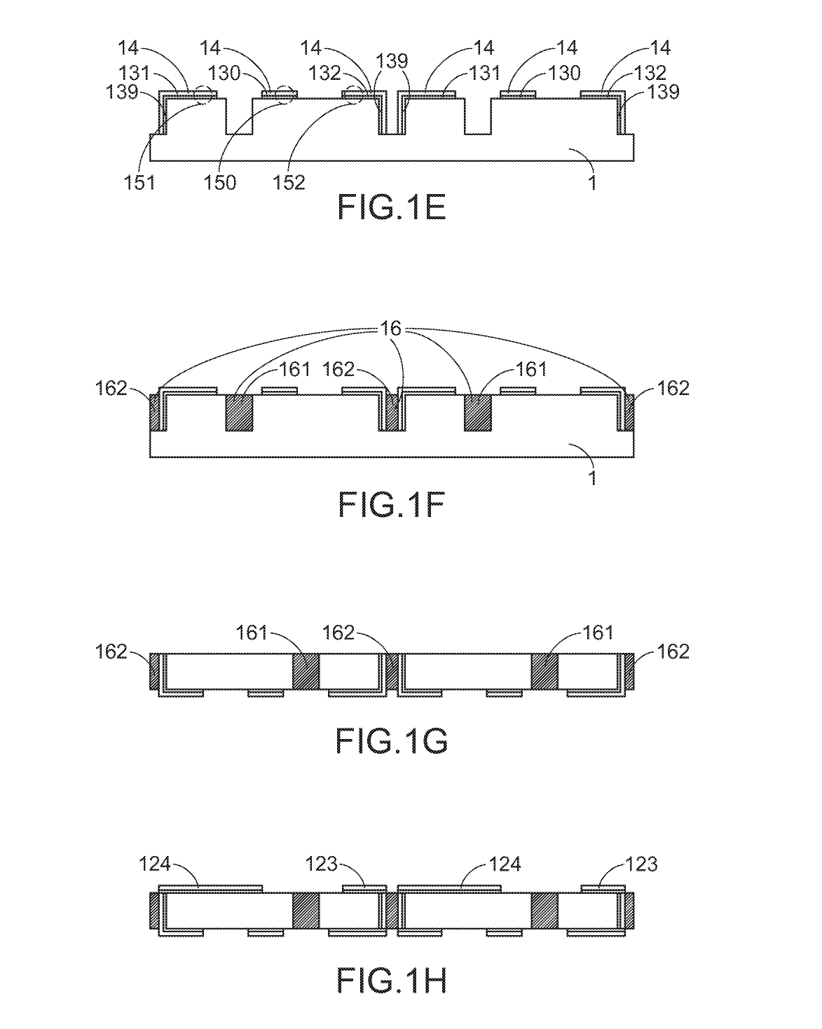

FIGS. 1A-1H illustrate a process flow of a fabricating method of a submount in accordance with an embodiment of the present invention. First, referring to FIG. 1A, a semiconductor substrate is provided. The semiconductor substrate can be selected from a group consisting of a silicon substrate, a germanium substrate and a gallium arsenide substrate. In the present embodiment, for example, the semiconductor substrate is, but not limited to, a silicon substrate 1, which has a thickness of 750 micrometers. The silicon substrate 1 includes a first surface 11 and a second surface 12 opposite to the first surface 11.

Next, referring to FIG. 1B, the silicon substrate 1 is processed. In detail, an isolating groove 110 is formed on the first surface 11, thereby defining a first region 111 and a second region 112 of the silicon substrate 1. The step of forming the isolating groove 110 can be performed repeatedly. Thus, a number of isolating grooves 110 can be formed, and a number of first regions 111 and a number of second regions 112 can be defined correspondingly. In another embodiment, the isolating grooves 110 are formed simultaneously. In addition, in the process of forming the isolating groove 110, a number of cutting notches 119 can be formed on the first surface 11. In the present embodiment, a width of the isolating groove 110 and a width of each cutting notch 119 are respectively in a range from 100 micrometers to 250 micrometers. Thus, the isolating groove 110 and the cutting notches 119 can be formed by a mechanical cutting machine with low cost. If the width of the isolating groove 110 and the width of each cutting notch 119 are reduced, the isolating groove 110 and the cutting notches 119 can also be formed by a laser or a photolithography process with high precise. Additionally, a depth of the isolating groove 110 is greater than a distance between the bottom of the isolating groove 110 and the second surface 12.

Next, referring to FIG. 1C, an electrical conductive layer 13 is formed on the first surface 11 of the silicon substrate 1 conformably. For example, the electrical conductive layer 13 can be a titanium-copper alloy layer or other suitable metallic layer, which can be deposited on the first surface 11 by a physical vapor deposition (PVD) method. Next, referring to FIG. 1D, the electrical conductive layer 13 is patterned. In detail, in the present embodiment, for example, a photolithography process is performed to form a patterned photoresist layer (not shown) to expose the portion of the electrical conductive layer 13. Then, the electrical conductive layer 13 is etched to remove the exposed portion of the electrical conductive layer 13 by using the patterned photoresist as a mask. The electrical conductive layer 13 can be etched by either a wet etching process or a dry etching process. Thereafter, the patterned photoresist is removed. As a result, a first electrical conductor 131 in the first region 111, a second electrical conductor 132 in the second region 112 and a chip carrying element 130 are defined. Besides, a number of interconnecting electrodes 139 are defined in the cutting notches 119. Each of the interconnecting electrodes 139 is respectively electrically connected to the first electrical conductor 131 or the second electrical conductor 132 on two sides of the corresponding cutting notch 119.

Next, referring to FIG. 1E, an electroplating process is applied to the first electrical conductor 131, the second electrical conductor 132, the chip carrying element 130 and the interconnecting electrodes 139 so as to form the first electrode 151, the second electrode 152 and the chip carrying layer 150. In detail, an electrical conductive metallic layer 14, for example, either a copper layer or a golden layer, is formed on the first electrical conductor 131, the second electrical conductor 132, the chip carrying element 130 and the interconnecting electrodes 139 to thicken the first electrical conductor 131, the second electrical conductor 132, the chip carrying element 130 and the interconnecting electrodes 139. It is noted that, the first electrode 151, the second electrode 152 and the chip carrying layer 150 can also be entirely formed by the above PVD method. However, the formation of the first electrode 151, the second electrode 152 and chip carrying layer 150 is time-consuming.

Next, referring to FIG. 1F, a first insulating adhesive member 161 is filled in the isolating groove 110 and a second insulating adhesive member 162 is filled in each of the cutting notches 119. Filling the first insulating adhesive member 161 in the isolating groove 100 and filling the second insulating adhesive members 162 in the cutting notches 119 further includes the following steps. An insulating adhesive material is heated. The heated insulating adhesive material is filled in the isolating groove 110 and the cutting notches 119 through an adhesive injecting machine. The insulating adhesive material filled in the isolating groove 110 and the cutting notches 119 is cooled to be solidified so as to form an insulating adhesive member 16 including the first insulating adhesive member 161 and the second insulating adhesive member 162. The first insulating adhesive member 161 and the second insulating adhesive member 162 are respectively selected from a group consisting of epoxy, polyurethane, silicone and acrylic. Next, the silicon substrate 1 is turned over. Referring to FIG. 1G, the silicon substrate 1 is thinned from the second surface 12 so as to expose the insulating adhesive member 16 from the second surface 12, thereby achieving insulation between the first region 111 and the second region 112 of the silicon substrate 1. The silicon substrate 1 can be directly thinned by a mechanical grinding process performed on the second surface 12. Otherwise, thinning the silicon substrate 1 can further include the following steps. The second surface 12 of the silicon substrate 1 is ground. Then, an etching process is applied to the second surface 12 of the ground silicon substrate 1 so that the insulating adhesive member 16 is exposed from the second surface 12. The etching process can be either a dry etching process or a wet etching process. The etching process can also be substituted by a chemical mechanical polishing (CMP) process.

Next, referring to FIG. 1H, a third electrode 123 and a fourth electrode 124 are formed on the second surface 12 of the silicon substrate 1. The third electrode 123 and the fourth electrode 124 respectively electrically connected to the interconnecting electrode 139 in the corresponding cutting notch 119. A process of forming the third electrode 123 and the fourth electrode 124 is similar to the process of forming the first electrode 151 and the second electrode 152. An electrical conductive layer (not labeled) is formed on the second surface 12 of the thinned silicon substrate 1. A photolithography process is performed on the electrical conductive layer to define a third electrical conductor (not labeled) and a fourth electrical conductor (not labeled). An electroplating process is applied to the third electrical conductor and the fourth electrical conductor so as to form the third electrode 123 and the fourth electrode 124.

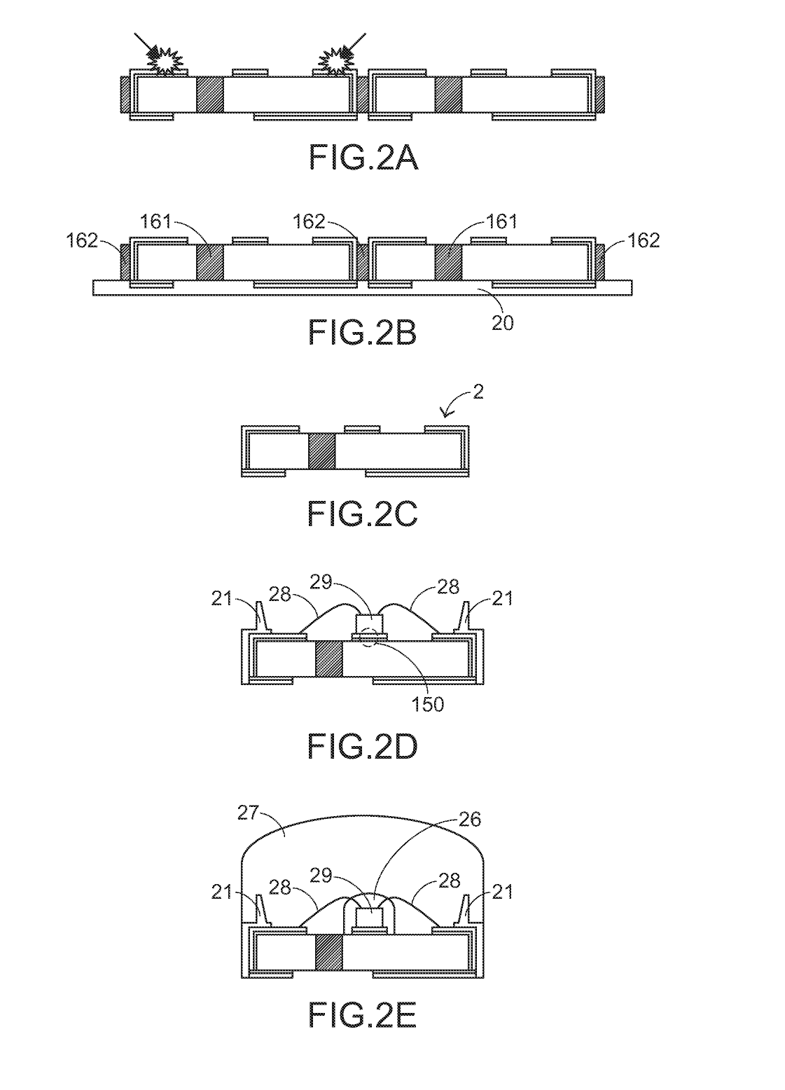

FIGS. 2A-2E illustrate schematic views of testing a submount and packaging an LED using the submount in accordance with an embodiment of the present invention. First, referring to FIG. 2A, the submounts of the silicon substrate 1 are tested by probes so as to judge whether each of the submounts is qualified. Referring to FIG. 2B, the silicon substrate 1 is adhered onto a dicing tape 20. Thus, the silicon substrate 1 can be cut at the cutting notches 119, in other words, through the second insulating adhesive member 162, thereby separating the silicon substrate 1 into a number of submounts 2 as shown in FIG. 2C. The submount 2 can be applied to package the high power components such as LEDs, power transistors, and so on, for thermal dissipation. In the following description, for example, the submount 2 is applied to package an LED.

Referring to FIG. 2D, a reflecting ring 21 is disposed on the submount 2. An LED 29 is disposed on the chip carrying layer 150. The LED 29 is electrically connected to the first electrode 151 and the second electrode 152 through wires 28. Referring to FIG. 2E, the LED 29 is coated with a fluorescence material 26 and covered by a lens structure 27, thereby forming a light emitting device having two electrical connection nodes on the bottom thereof.

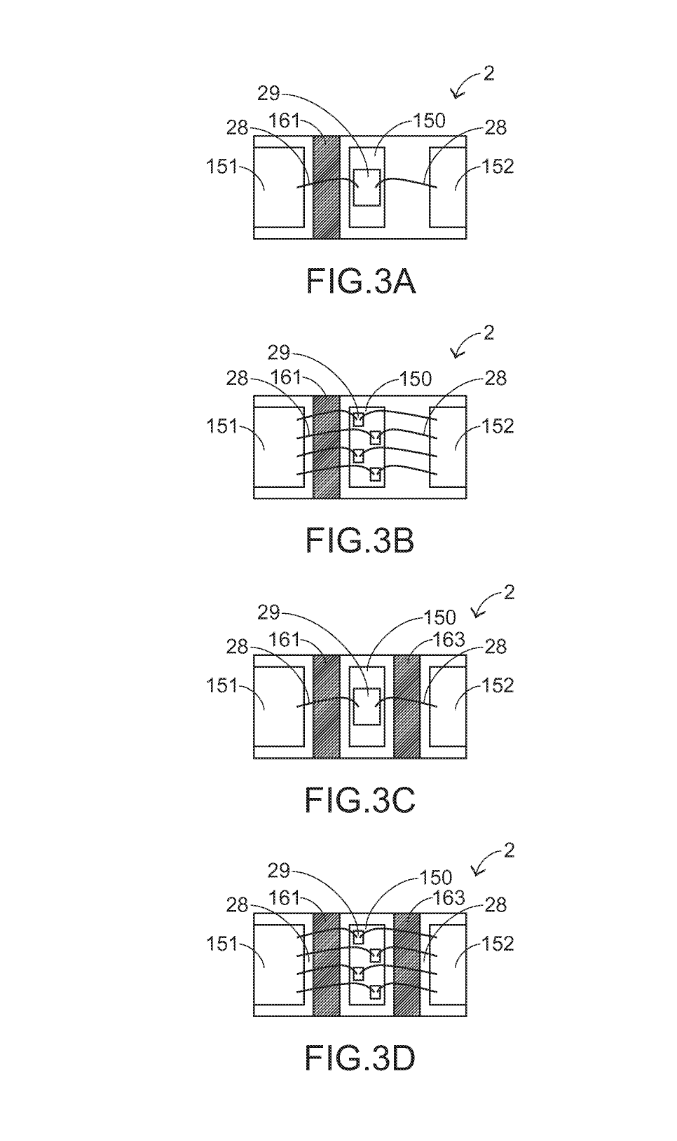

FIG. 3A illustrates a top, schematic view of a submount having a LED mounted thereon in accordance with an embodiment of the present invention. Referring to FIG. 3A, the LED 29 is mounted on the submount 2. The first electrode 151 in the first region 111 is isolated from the second electrode 152 in the second region 112 and the chip carrying layer 150 by the first insulating adhesive member 161. Thus, the first insulating adhesive member 161 has a function of insulating the first region 111 from the second region 112. Meanwhile, the first insulating adhesive member 161 has a function of preventing the heat generated form the LED 29 from being transmitted to the first electrical conductor 131. FIG. 3B illustrates a top, schematic view of a submount having a number of LEDs mounted thereon in accordance with an embodiment of the present invention. Similar to the above embodiment illustrated by FIG. 3A, in the embodiment, a number of LEDs 29 are mounted on the submount 2, which are not described repeatedly here.

FIGS. 3C and 3D illustrate top, schematic views of a submount having a third insulating adhesive member in accordance with an embodiment of the present invention. Referring to FIGS. 3C and 3D, a third insulating adhesive member 163 is further formed in a submount 2. Thus, the first electrode 151, the second electrode 152 and the chip carrying layer 150 are isolated from each other by means of the first insulating adhesive member 161 and the third insulating adhesive member 163, thereby improving insulation effect. The third insulating adhesive member 163 can be selected from a group consisting of epoxy, polyurethane, silicone and acrylic.

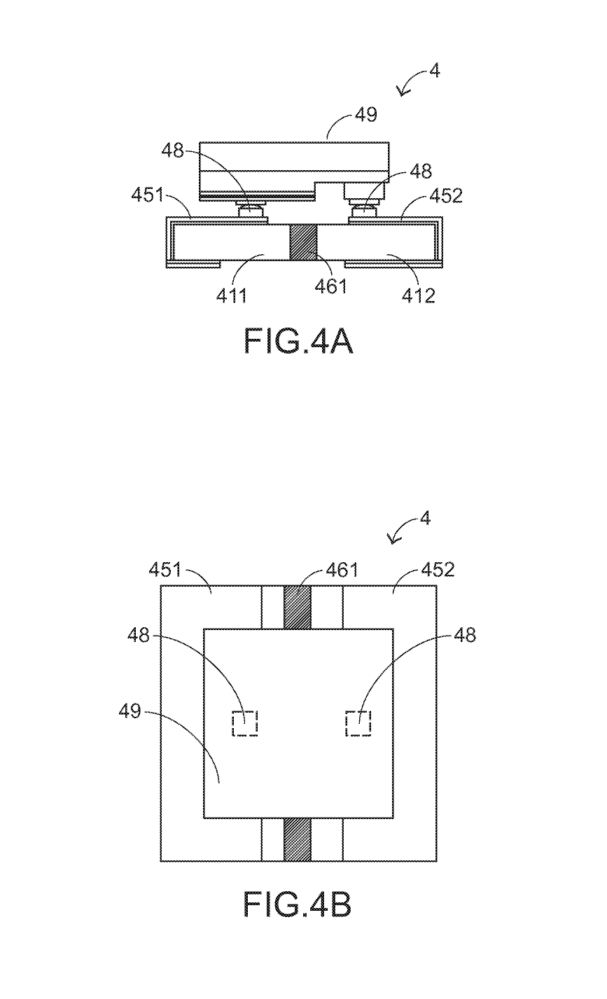

FIG. 4A illustrates a cross-sectional, schematic view of a submount having an LED in flip chip package in accordance with an embodiment of the present invention. FIG. 4B illustrates a top, schematic view of a submount having an LED in flip chip package in accordance with an embodiment of the present invention. Referring to FIGS. 4A and 4B, an LED 49 is mounted on the submount 4 in a flip chip manner. The LED 49 is electrically connected to the first electrode 451 in the first region 411 and the second electrode 452 in the second region 412 through the respective pad 48. The first electrode 451 and the second electrode 452 are isolated by the first insulating adhesive member 461. Thus, a similar insulation effect can be achieved. The first insulating adhesive member 461 can be selected from a group consisting of epoxy, polyurethane, silicone and acrylic.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A fabricating method of a submount, comprising:
providing a semiconductor substrate having a first surface and a second surface opposite to the first surface;
forming an isolating groove on the first surface, thereby defining a first region and a second region of the semiconductor substrate;
forming a first electrode on the first surface in the first region and a second electrode on the first surface in the second region respectively;
filling a first insulating adhesive member in the isolating groove; and
thinning the semiconductor substrate from the second surface so as to expose the first insulating adhesive member from the second surface, thereby insulating the first region of the semiconductor substrate from the second region of the semiconductor substrate.

2. The fabricating method as claimed in claim 1, wherein the semiconductor substrate is selected from a group consisting of a silicon substrate, a germanium substrate and a gallium arsenide substrate.

3. The fabricating method as claimed in claim 1, wherein a depth of the isolating groove is greater than a distance between a bottom of the isolating groove and the second surface.

4. The fabricating method as claimed in claim 1, wherein the step of forming the first electrode and the second electrode further comprises:
forming an electrical conductive layer on the first surface of the semiconductor substrate;
performing a photolithography process on the electrical conductive layer so as to define a first electrical conductor in the first region and a second electrical conductor in the second region; and
applying an electroplating process to the first electrical conductor and the second electrical conductor so as to form the first electrode and the second electrode.

5. The fabricating method as claimed in claim 1, wherein the step of filling the first insulating adhesive member in the isolating groove further comprises:
heating an insulating adhesive material;
filling the heated insulating adhesive material into the isolating groove through an adhesive injecting machine; and
solidifying the insulating adhesive material so as to form the first insulating adhesive member.

6. The fabricating method as claimed in claim 1, wherein the step of thinning the semiconductor substrate comprises:
grinding the second surface of the semiconductor; and
applying an etching process to the second surface of the ground semiconductor substrate so that the insulating adhesive member is exposed from the second surface.

7. The fabricating method as claimed in claim 6, wherein the etching process is either a dry etching process or a wet etching process.

8. The fabricating method as claimed in claim 1, wherein in the step of forming the isolating groove, a plurality of cutting notches are further formed on the first surface of the semiconductor substrate, and a plurality of interconnecting electrodes are formed in the cutting notches correspondingly, each of the interconnecting electrodes being electrically connected to a corresponding first electrode or a corresponding second electrode.

9. The fabricating method as claimed in claim 8, further comprising:
filling a second insulating adhesive member in the cutting notches; and
forming a third electrode and a fourth electrode on the second surface of the thinned semiconductor substrate wherein the third electrode and the fourth electrode are respectively electrically connected to the interconnecting electrode in the corresponding cutting notch.

10. The fabricating method as claimed in claim 9, wherein the step of forming the third electrode and the fourth electrode comprises:
forming another electrical conductive layer on the second surface of the thinned semiconductor substrate;
performing a photolithography process on the another electrical conductive layer to define a third electrical conductor and a fourth electrical conductor; and
applying an electroplating process to the third electrical conductor and the fourth electrical conductor so as to form the third electrode and the fourth electrode.

11. A submount, comprising:
a semiconductor substrate having a first surface and a second surface opposite to the first surface, the first surface comprising an isolating groove, thereby defining a first region and a second region of the semiconductor substrate;
a first electrode formed in the first region and a second electrode formed in the second region, the first electrode and the second electrode being configured for electrically connecting two electrodes of an electronic component respectively; and
a first insulating adhesive member filled in the isolating groove, and exposed from the second surface after the semiconductor substrate is thinned, thereby insulating the first region of the semiconductor substrate from the second region of the semiconductor substrate.

12. The submount as claimed in claim 11, wherein the semiconductor substrate is selected from a group consisting of a silicon substrate, a germanium substrate and a gallium arsenide substrate.

13. The submount as claimed in claim 11, wherein a depth of the isolating groove is greater than a distance between a bottom of the isolating groove and the second surface.

14. The submount as claimed in claim 11, wherein the first electrode and the second electrode respectively comprise a titanium-copper alloy layer and a copper layer.

15. The submount as claimed in claim 11, wherein the first insulating adhesive member is selected from a group consisting of epoxy, polyurethane, silicone and acrylic.

16. The submount as claimed in claim 11, further comprising:
a plurality of cutting notches formed on the first surface of the semiconductor substrate;
a plurality of interconnecting electrodes formed in the cutting notches correspondingly, each of the interconnecting electrodes being electrically connected to a corresponding first electrode or a corresponding second electrode;
a second insulating adhesive member filled in the cutting notches; and
a third electrode and a fourth electrode formed on the second surface of the thinned semiconductor substrate and electrically connected to the interconnecting electrode in the corresponding cutting notch.

17. The submount as claimed in claim 11, wherein the third electrode and the fourth electrode respectively comprise a titanium-copper alloy layer and a copper layer.

18. The submount as claimed in claim 11, wherein the second insulating adhesive member is selected from a group consisting of epoxy, polyurethane, silicone and acrylic.
